(19) United States
(12) Patent Application Publication
(10) Pub. No.: US 2012/0133242 A1
(43) Pub. Date: May 31, 2012

(54) MICROMECHANICAL COMPONENT AND PRODUCTION METHOD FOR A MICROMECHANICAL COMPONENT

(76) Inventors: Frederic Njikam Njimonzie, Reutlingen (DE); Joerg Muchow, Reutlingen (DE); Zoltan Lestyan, Martonvasar (HU); Wolfram Schock, Rommelsbach (DE)

(21) Appl. No.: 13/320,712

(22) PCT Filed: May 18, 2010
(86) PCT No.: PCT/EP10/56813

§ 371 Date: Feb. 1, 2012

(30) Foreign Application Priority Data
May 27, 2009 (DE) 10 2009 026 507.4

(51) Int. Cl. H02N 1/00; H05K 13/00

(52) U.S. Cl. 310/300; 29/592.1

(57) ABSTRACT

A micromechanical component has an outer stator electrode component and an outer actuator electrode component which is connected to a holder via at least one outer spring, an adjustable element being adjustable about a first rotation axis by application of a first voltage between the outer actuator electrode component and the outer stator electrode component, and having an inner stator electrode component and an inner actuator electrode component having a first web with at least one electrode finger disposed thereon, the adjustable element being adjustable about a second rotation axis by application of a second voltage between the at least one electrode finger of the inner actuator electrode component and the inner stator electrode component, and the inner actuator electrode component being connected to the outer actuator electrode component via an intermediate spring which is oriented along the second rotation axis. Also described is a production method for a micromechanical component.

### FIELD OF THE INVENTION

The present invention relates to a micromechanical component. The present invention further relates to a production method for a micromechanical component.

### BACKGROUND INFORMATION

A micromechanical component often has an electrostatic and/or magnetic drive configured to adjust at least one adjustable element about at least one rotation axis in relation to a holder of the micromechanical component. Such a micromechanical component may, for example, be constructed as a micromirror. A micromirror of unpublished European Patent Application EP 08400007.4 is described below as an example of a micromechanical component:

FIG. 1 shows a schematic illustration of a conventional micromirror.

The micromirror illustrated has, as an adjustable element, mirror plate 10 which is adjustable about a first rotation axis 12 and a second rotation axis 14 in relation to a holder (not shown). Mirror plate 10 is connected to an inner frame 18 via two inner springs 16 extending along first rotation axis 12. Webs 20, which extend along second rotation axis 14, are fastened at two opposite locations of inner frame 18. Each of the two webs 20 is connected at the end thereof pointing away from inner frame 18 to the holder by a respective outer spring 22 which extends along second rotation axis 14.

In addition, an outer actuator electrode component 24 and an inner actuator electrode component 26 are disposed on each of webs 20. Outer actuator electrode component 24 includes electrode fingers 24a which extend on both sides of associated web 20 perpendicularly to second rotation axis 14. Correspondingly, electrode fingers 26a and 26b of inner actuator electrode component 26 are oriented perpendicularly to second rotation axis 14, electrode fingers 26a being disposed on a first side of second rotation axis 14 and electrode fingers 26b being disposed on a second side of second rotation axis 14. In the example illustrated in FIG. 1, electrode fingers 24a of outer actuator electrode component 24 are of a constant length. The lengths of electrode fingers 26a and 26b of inner actuator electrode component 26 decrease with increasing distance from inner frame 18.

Fastened to the holder are two outer stator electrode components 28 and two inner stator electrode components 30. An outer stator electrode component 28 is in each case disposed adjacent to an associated outer actuator electrode component 24. Correspondingly, an inner actuator electrode component 26 is associated with each of the two inner stator electrode components 30. Each of the stator electrode components 28 and 30 includes electrode fingers 28a, 30a and 30b.

In the case of the micromirror illustrated, a first voltage not equal to zero may be applied between electrode fingers 24a of an outer actuator electrode component 24 and electrode fingers 28a of associated outer stator electrode component 28. If the first voltage is applied between those electrode fingers 24a and 28a of outer electrode components 24 and 28 which are disposed on a first side of first rotation axis 12, then mirror plate 10 is adjusted about first rotation axis 12 in a first direction of rotation. Correspondingly, if the first voltage is applied between electrode fingers 24a and 28a of outer electrode components 24 and 28 on a second side of first rotation axis 12, mirror plate 10 is rotated about first rotation axis 12 in a second direction of rotation.

Electrode fingers 26a, 26b, 30a and 30b of inner electrode components 26 and 30 are contactable in such a manner that a second voltage may be applied solely between electrode fingers 26a and 30a of the two inner electrode components 26 and 30, which electrode fingers 26a and 30a are disposed on the first side of second rotation axis 14. Independently thereof, the second voltage may also be applied solely between electrode fingers 26b and 30b of the two inner electrode components 26 and 30, which electrode fingers 26b and 30b are disposed on the second side of rotation axis 14. Depending on the application of the second voltage between electrode fingers 26a and 30a disposed on the first side of second rotation axis 14 or between electrode fingers 26b and 30b disposed on the second side of rotation axis 14, mirror plate 10 is adjusted about second rotation axis 14 in a particular direction of rotation.

To better illustrate the disadvantages of the conventional micromirror of FIG. 1, reference is made to the following Figures.

FIGS. 2A and 2B show cross-sections through an outer actuator electrode component of the conventional micromirror of FIG. 1.

In the schematic illustrations of FIGS. 2A and 2B, a first voltage U1 equal to zero is applied between electrode fingers 24a of outer actuator electrode components 24 and electrode fingers 28a of outer stator electrode components 28. In FIG. 2A, the second voltage U2 that may be applied between electrode fingers 26a and 30a or between electrode fingers 26b and 30b of inner electrode components 26 and 30 is also equal to zero. In the no-voltage state in which voltages U1 and U2 that may be applied are equal to zero, electrode fingers 24a and 28a of outer electrode components 24 and 28 lie parallel to one another in two different planes. One also speaks here of an out-of-plane arrangement of electrode fingers 26a and 28a of outer electrode components 24 and 28 in the no-voltage state.

By contrast, FIG. 2B shows a situation in which a second voltage U2 that is not equal to zero is applied between electrode fingers 26a and 30a of inner electrode components 26 and 30, which electrode fingers 26a and 30a are disposed on the first side of second rotation axis 14. As will be seen, the application of a second voltage U2 that is not equal to zero between electrode fingers (not shown) 26a and 30a or 26b and 30b of inner electrode components 26 and 30 also causes adjustment of electrode fingers 24a of outer actuator electrode component 24 about second rotation axis 14. This may lead, for example, to overlapping of electrode fingers 24a and 28a belonging to outer electrode components 24 and 28 and disposed on the first side of second rotation axis 14, whereas electrode fingers 24a and 28a belonging to outer electrode components 24 and 28 and disposed on the second side of second rotation axis 14 do not overlap. If, in a situation such as that shown in FIG. 2B, a first voltage U1 that is not equal to zero is applied between electrode fingers 24a and 28a of outer electrode components 24 and 28, the applied first voltage U1 additionally causes a crosstalk-torque about the second rotation axis. That crosstalk-torque often leads to an undesired adjustment of mirror plate 10 about second rotation axis 14. This may also be described as crosstalk of the micromirror or as undesirable coupling between the possible adjustment movements of mirror plate 10 about the two rotation axes 12 and 14. The disadvantage here is that this effect becomes greater with an increase in the applied second voltage U2, in other words with an increase in the second mirror-adjustment angle by which mirror plate 10 is adjusted about second rotation axis 14. It is therefore desirable to have a micromechanical component that corresponds to the preamble of claim 1 and in which there is no coupling between the two possible adjustment movements of the adjustable element.

### SUMMARY OF THE INVENTION

The exemplary embodiments and/or exemplary methods of the present invention provide a micromechanical component having the features described herein, and a production method for a micromechanical component having the features described herein.

By the intermediate spring disposed between the outer actuator electrode component and the inner actuator electrode component it is ensured that the outer actuator electrode component is not moved or is hardly moved upon adjustment of the adjacent inner actuator electrode component about the second rotation axis. The outer actuator electrode component is accordingly decoupled from the rotational motion of the adjacent inner actuator electrode component about the second rotation axis. Accordingly, the rotational motion of the inner actuator electrode component about the second rotation axis does not cause an overlap between the outer electrode components that is unsymmetrical with respect to the second rotation axis. The application of a first voltage that is not equal to zero between the outer electrode components is therefore also unable to cause any significant crosstalk-torque about the second rotation axis as in the case of the related art described above. It is thus ensured that the undesirable coupling between the two possible adjustment movements of the adjustable element is suppressed well. The exemplary embodiments and/or exemplary methods of the present invention thus offer an easily and inexpensively implemented possibility for preventing the crosstalk which often occurs conventionally.

In contrast to the conventional micromirror described above, with the present invention it is possible to obtain a micromechanical component in which exclusively electrode fingers of the inner actuator electrode component are formed along the first web. In that manner, a torque exertable on the adjustable element for adjustment of the adjustable element about the second rotation axis may be significantly increased relative to the overall length of the first web. It is thus possible to eliminate the disadvantage of many of the electrode fingers of the inner actuator electrode component being disposed at a comparatively small distance from the second rotation axis.

Furthermore, the outer actuator electrode component may have a second web with electrode fingers, which second web may be oriented non-parallel to the first web of the inner actuator electrode component and/or to the first rotation axis. Since the electrode fingers of the outer actuator electrode component are in that case disposed at an advantageously great distance from the first rotation axis, it is possible to obtain a high torque for adjustment of the adjustable element about the first rotation axis. In addition, with a non-parallel orientation of the first web and second web, a greater number of electrode fingers may be disposed on the two webs without this requiring an increase in the size of the micromechanical component along the first rotation axis and/or the second rotation axis.

Owing to the relatively large number of electrode fingers of the electrode component, a comparatively large force input is attainable. Accordingly, it is also possible for an adjustable element having a comparatively large mass to be adjusted by the micromechanical component. In addition, the spring stiffness of the at least one inner spring, the at least one intermediate spring and/or the at least one outer spring may be set comparatively high, so that the micromechanical component may be of a relatively robust construction.

Advantageous developments of the present invention are described herein.

The advantages of the micromechanical component are also afforded in a corresponding production method for a micromechanical component.

Further features and advantages of the present invention will be described below with reference to the Figures.

### BRIEF DESCRIPTION OF THE DRAWINGS

FIGS. 1, 2A, and 2B show a schematic illustration and cross-section of a conventional micromirror.

FIGS. 3, 4 and 6 to 13B show schematic illustrations of embodiments of the micromechanical component.

FIG. 5 shows a cross-section through a layer structure to illustrate an embodiment of the production method.

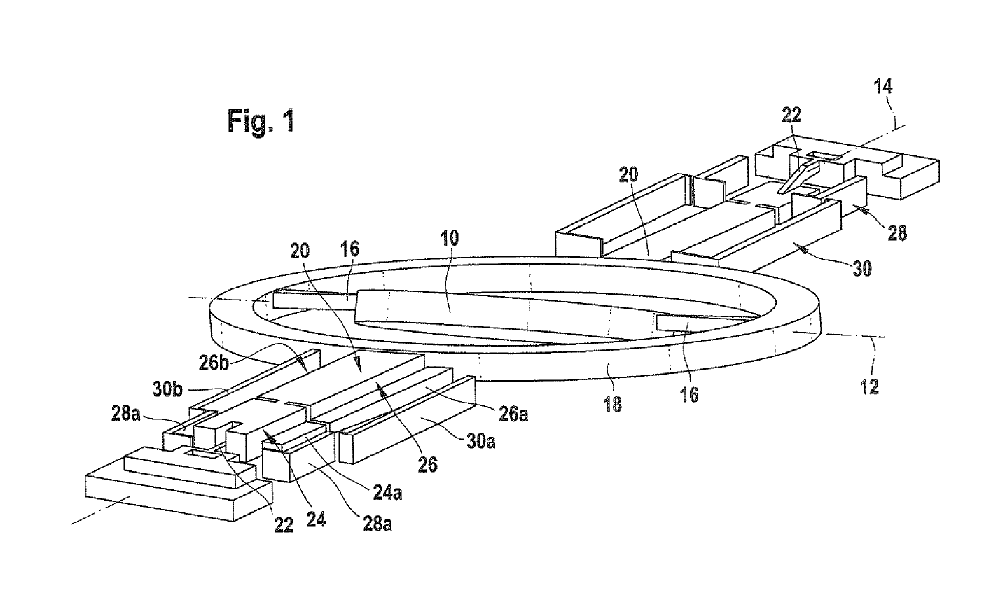

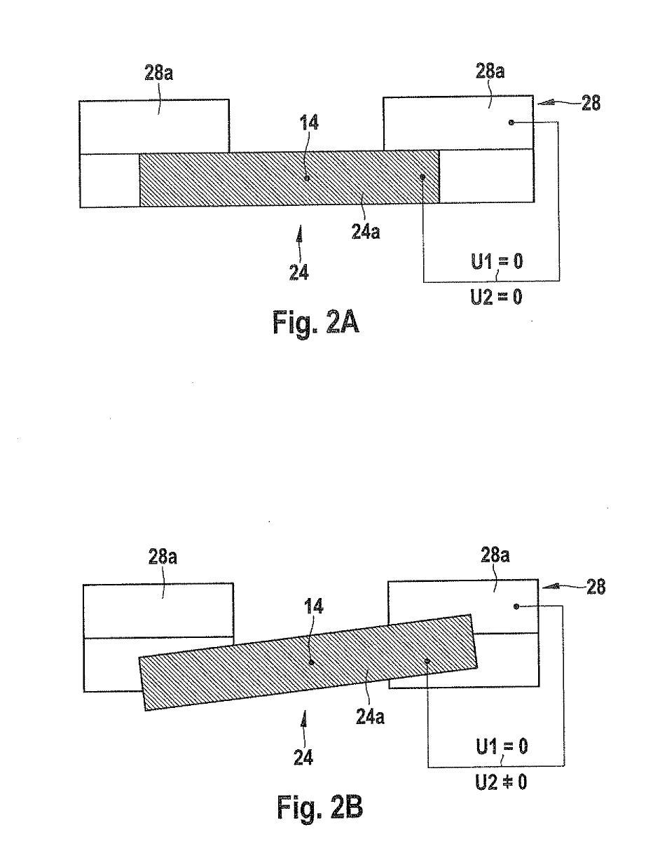

### DETAILED DESCRIPTION

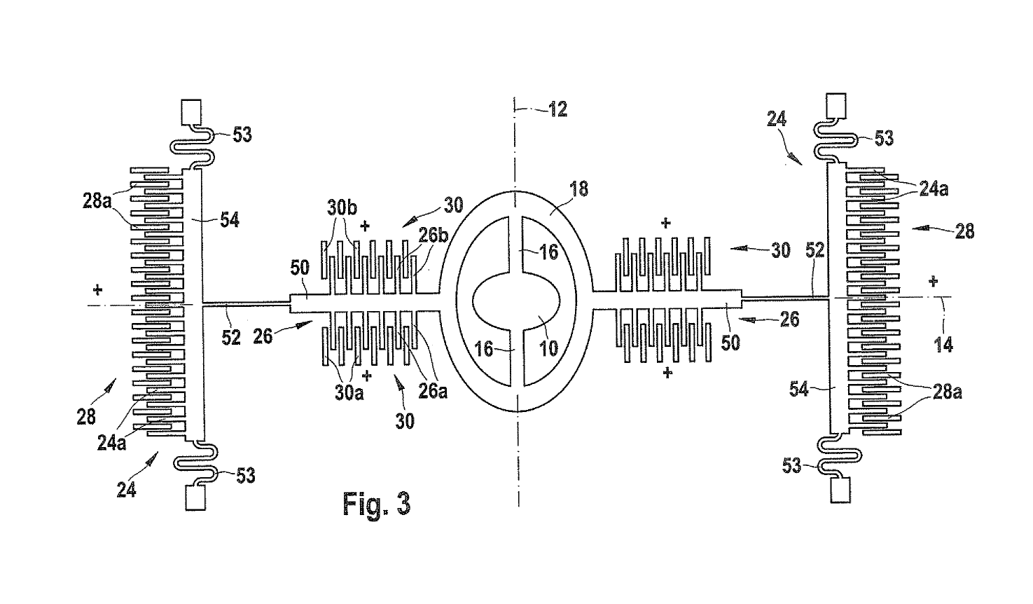

FIG. 3 shows a schematic illustration of a first embodiment of the micromechanical component.

The micromechanical component illustrated is constructed as a micromirror. The micromechanical component has a mirror plate 10 as the adjustable element. An advantageous reflection coefficient may be ensured by polishing and/or suitable coating of mirror plate 10.

It is pointed out that the micromechanical component is not limited to being constructed as a micromirror. Instead of or in addition to having mirror plate 10, the micromechanical component may also have a different adjustable element.

Mirror plate 10 is adjustable in relation to a holder (not shown) about a first rotation axis 12 and about a second rotation axis 14. Second rotation axis 14 is oriented non-parallel to first rotation axis 12. The second rotation axis 14 may form a right angle with first rotation axis 12. The micromechanical component described herein is not, however, limited to a perpendicular orientation of the two rotation axes 12 and 14. Embodiments of the micromechanical component in which the two rotation axes 12 and 14 form an angle of between 0° and 90° will also be apparent to the person skilled in the art by reference to the following description.

Mirror plate 10 is connected via at least one inner spring 16 to an inner frame 18. Inner frame 18 may also be referred to as a Cardan frame. For example, inner frame 18 is constructed as a Cardan ring. The at least one inner spring 16 may be a torsion spring oriented along first rotation axis 12. To improve stability, mirror plate 10 may be connected to inner frame 18 via two inner springs 16 disposed on two sides facing in opposite directions.

Fastened to inner frame 18 there is at least one inner actuator electrode component 26 having a first web 50 on which electrode fingers 26a and 26b are disposed. First web 50 is oriented along second rotation axis 14. The micromechanical component may have two such inner actuator electrode components 26, which are disposed on opposite sides of first rotation axis 12. Each of the two actuator electrode components 26 may in this case be formed on a respective associated first web 50. Each of the two inner actuator electrode components 26 may include a plurality of electrode fingers 26a and 26b, which are disposed on both sides of second rotation axis 14 and extend perpendicularly away from second rotation axis 14.

Adjacent to each inner actuator electrode component 26, an associated inner stator electrode component 30 is fixedly disposed on the holder. Each of inner stator electrode components 30 has electrode fingers 30a and 30b, which are associated with electrode fingers 26a and 26b of adjacent inner actuator electrode component 26. The orientation of electrode fingers 30a and 30b of inner stator electrode components 30 is adapted to electrode fingers 26a and 26b of adjacent inner actuator electrode component 26.

Electrode fingers 26a, 26b, 30a and 30b of inner electrode components 26 and 30 may be of a constant length. Inner electrode components 26 and 30 of the embodiment described herein with a constant length of electrode fingers 26a, 26b, 30a and 30b have the advantage of a greater attainable torque compared with electrode components in which the lengths of the electrode fingers decrease with increasing distance from inner frame 18. That greater attainable torque is guaranteed, since surfacing (emergence/exiting) of electrode fingers 26a and 26b is prevented. The function of inner electrode components 26 and 30 will be discussed in more specific detail hereinafter.

Each end of a first web 50 pointing away from mirror plate 10 is connected to an outer actuator electrode component 24 via an intermediate spring 52. Intermediate spring 52 formed between first web 50 and an outer actuator electrode component 24 is oriented along second rotation axis 14, that is, along a longitudinal axis of first web 50. Outer actuator electrode component 24 may be constructed as a comb electrode having a second web 54 and electrode fingers 24a disposed on second web 54. Further possible configurations for outer actuator electrode component 24 will be described hereinafter.

The outer actuator electrode component is connected to the holder (not shown) via at least one outer spring. In the case of the embodiment illustrated, each outer actuator electrode component 24 is connected to the holder via two outer springs in the form of meander-shaped seesaw springs 53. The longitudinal directions of meander-shaped seesaw springs 53 extend in this case along a longitudinal axis of second web 54 of outer actuator electrode component 24 and parallel to first rotation axis 12.

The at least one intermediate spring 52 has a comparatively small spring stiffness in respect of torsion of intermediate spring 52 about second rotation axis 14. By contrast, the at least one outer spring, via which an outer actuator electrode component 24 is connected to the holder, is so constructed that a second spring stiffness of the at least one outer spring, which opposes rotational motion of the outer actuator electrode component about second rotation axis 14, is greater than the first spring stiffness of intermediate spring 52. An advantageously great second (virtual) spring stiffness is attainable, for example, over both meander-shaped seesaw springs 53.

Whereas, therefore, it is possible for torsion of intermediate spring 52 about second rotation axis 14 to be carried out with a relatively small force, comparatively great force is required to cause rotational motion of outer actuator electrode component 24 about second rotation axis 14.

In that manner it is ensured that, upon rotational motion of an inner actuator electrode component 26 about second rotation axis 14, adjacent outer actuator electrode component 24 is not moved concomitantly. This may be described as a decoupling of outer actuator electrode component 24 from the rotational motion of adjacent inner actuator electrode component 26 about second rotation axis 14. The disadvantageous crosstalk which occurs in the case of the related art is reliably suppressed by such a decoupling in the case of the micromechanical component described herein.

Second web 54 of the at least one outer actuator electrode component 24 may be oriented non-parallel to first web 50 of adjacent inner actuator electrode component 26, which web 50 extends along second rotation axis 14. In this case, it is possible for webs 50 and 54 to be longer than in the related art without increasing the extent of the micromechanical component along first rotation axis 12 and/or along second rotation axis 14. Thus, while retaining what may be a preferred size of the micromechanical component, a greater number of electrode fingers 26a and 26b may be disposed on the at least one first web 50 and/or a greater number of electrode fingers 24a may be disposed on the at least one second web 54. This results in an increase in the attainable torques for adjustment of mirror plate 10 about first rotation axis 12 and/or about second rotation axis 14. Second web 54 may, in particular, be oriented perpendicularly to first web 50.

Owing to the relatively high attainable torques, it is possible for springs 16, 52 and 53 to be of a comparatively stiff design. That ensures an advantageous robustness of the micromechanical component. In addition, this makes the production of springs 16, 52 and 53 easier. Furthermore, the spring stiffness of springs 16, 52 and 53 may be defined in such a manner that the undesirable crosstalk is prevented in the manner described above.

Electrode fingers 24a formed perpendicular to second web 54 and belonging to the at least one outer actuator electrode component 24 are at a comparatively great distance from the first rotation axis, which additionally ensures a relatively high torque for adjustment of mirror plate 10 about first rotation axis 12. For that reason, the number of electrode fingers 24a and 28a of outer actuator electrode components 24 and 28 may be reduced in order to ensure sufficient mounting area for electrode fingers 26a, 26b, 30a and 30b of inner electrode components 26 and 30. In that manner, the driving force for adjusting mirror plate 10 about second rotation axis 14 may be additionally increased.

Associated with each of outer actuator electrode components 24 there is an outer stator electrode component 28 which is fastened to the holder. Each of outer stator electrode components 28 includes electrode fingers 28a the orientation and position of which correspond to electrode fingers 24a of associated outer actuator electrode component 24.

Outer electrode components 24 and 28 are contactable in such a manner that a first voltage not equal to zero may be applied between electrode fingers 24a and 28a on a first side of first rotation axis 12, it being ensured at the same time that there is no voltage between electrode fingers 24a and 28a on the second side of first rotation axis 12. Similarly, a first voltage not equal to zero may be applied between electrode fingers 24a and 28a on the second side of first rotation axis 12 without there being a voltage between electrode fingers 24a and 28a on the first side.

Furthermore, inner electrode components 26 and 30 are contactable in such a manner that a second voltage not equal to zero may be applied between electrode fingers 26a and 30a disposed on the first side of second rotation axis 14, while there is no voltage between electrode fingers 26b and 30b disposed on the second side of second rotation axis 14. In addition, the second voltage may also be applied between electrode fingers 26b and 30b disposed on the second side of second rotation axis 14, while the voltage between electrode fingers 26a and 30a disposed on the first side of second rotation axis 14 is equal to zero.

The formation of suitable contact elements (for example lines) and of a control device (not shown) for applying the first voltage and the second voltage will be apparent to one skilled in the art by reference to FIG. 3. A more detailed description of those components will therefore be dispensed with.

In the no-voltage state, that is, if a voltage is not present between any of electrode components 24, 26, 28, 30, actuator electrode components 24 and 26 and mirror plate 10 are situated in a starting position which may lie in a common starting plane. Electrode fingers 28a, 30a and/or 30b of a stator electrode component 28 and/or 30 may be situated on a side of the starting plane facing away from the holder. Equally, electrode fingers 28a, 30a and/or 30b of a stator electrode component 28 and/or 30 may be situated in a plane between the starting plane and the holder.

The adjustment of mirror plate 10 about first rotation axis 12 may be effected resonantly. In that case, the control device is configured to provide as first voltage a voltage signal having a frequency equal to a natural frequency of an oscillating motion of mirror plate 10 in relation to inner frame 18, accompanied by a bending of the at least one inner spring 16. In that manner, with suitably defined values for the mass of mirror plate 10 and for the spring stiffness of the at least one inner spring 16, it is possible to excite specifically a resonant oscillating motion of mirror plate 10 about first rotation axis 12 in relation to inner frame 18, accompanied by a bending of the at least one inner spring 16. That causes an increase in the mirror adjustment angle. For example, in that manner, mirror plate 10 may be adjusted about first rotation axis 12 by a mirror adjustment angle of 12° in relation to the holder, whereas outer actuator electrode component 24 is tilted about first rotation axis 12 merely by an angle of rotation <<1° in relation to the holder. A voltage signal having a frequency of approximately 20 kHz may be provided as the first voltage.

With the micromechanical component illustrated in FIG. 3 it is possible to obtain an image projection. The image projection may be effected by generating a line-form image structure. In the case of what may be a preferred actuation of the micromechanical component, the voltages are applied in such a manner that mirror plate 10 is set into a first oscillating motion about first rotation axis 12 with a frequency of 20 kHz. At the same time, mirror plate 10 is set into a second, quasi-static motion about second rotation axis 14 with a frequency of 60 Hz. The second, quasi-static motion of mirror plate 10 is often also referred to as a sawtooth-shaped quasi-static motion. The micromechanical component fulfills the function of a microscanner well in this case.

Compared with the conventional micromirror, which is a two-spring-two-mass system, the micromechanical component described in the above paragraphs is constructed as a four-spring-four-mass system.

In an exemplary embodiment of the micromechanical component illustrated, the entire drive train, that is, the at least one outer actuator electrode component 24 and the at least one inner actuator electrode component 26, is connected to ground. In that case, it is not necessary to pass higher voltages via the at least one outer spring and the at least one intermediate spring 52. For that reason, the lines routed via springs 52 and 53 do not have to be of a construction such that they withstand high voltages. In that manner it is ensured that the spring stiffness of springs 52 and 53 are not affected by lines configured specifically for applying high voltages.

The high potentials for providing the first voltage and the second voltage are applied to stator electrode components 28 and 30 from the outside. This may be accomplished with comparatively little expenditure. In particular, the lines used for applying the high potentials may in this case be produced inexpensively and in a simple manner.

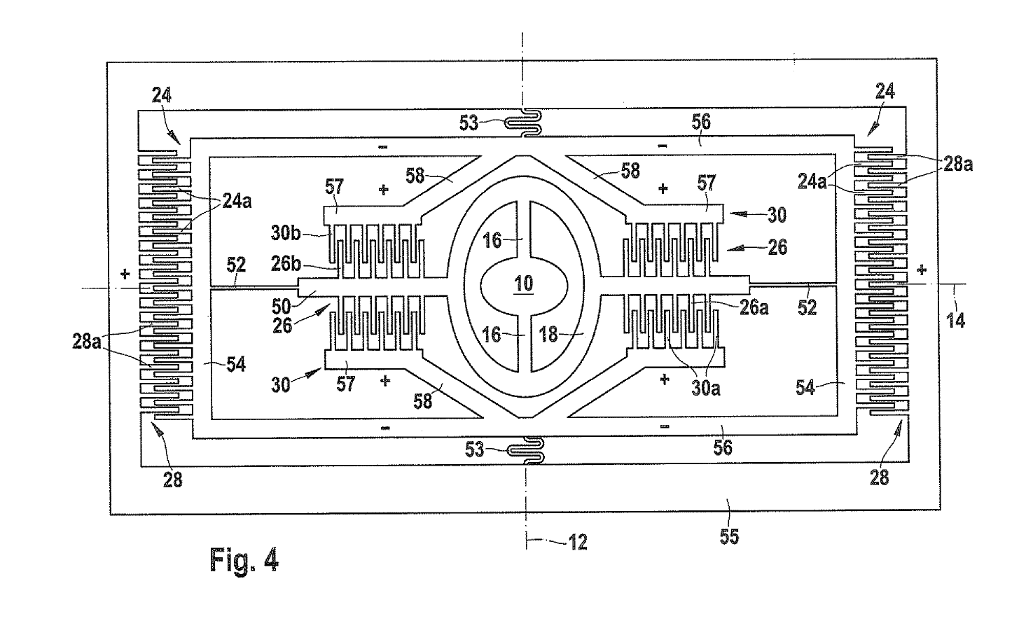

FIG. 4 shows a schematic illustration of a second embodiment of the micromechanical component.

In the case of the embodiment illustrated, as a supplement to the embodiment of FIG. 3 described in the foregoing, second webs 54 of outer actuator electrode components 24 are connected to each other via two connecting webs 56. Each of the two connecting webs 56 interconnects two ends of second webs 54 pointing away from second rotation axis 14 on one side. In that manner, second webs 54 and connecting webs 56 form an intermediate frame. The intermediate frame may be formed as a rectangle from components 54 and 56.

The intermediate frame formed by components 54 and 56 is connected to the holder via two outer springs constructed as meander-shaped seesaw springs 53. The two longitudinal axes of meander-shaped seesaw springs 53 lie on first rotation axis 12. The holder may, for example, be in the form of outer frame 55. Electrode fingers 28a of outer stator electrode components 28 may in this case be fastened to inner surfaces of outer frame 55 that are oriented parallel to second webs 54. The micromechanical component is not, however, limited to such a construction of the holder.

Whereas the two outer stator electrode components 28 are therefore fixedly disposed on the holder, inner stator electrode components 30 are fastened to the intermediate frame formed by components 54 and 56. Accordingly, inner stator electrode components 30 are actuated with the intermediate frame by outer electrode components 24 and 28. To fasten inner stator electrode components 30 to the intermediate frame, webs 57 of inner stator electrode components 30 in the form of comb electrodes may each be connected to adjacent connecting web 56 by a respective fastening web 58.

The voltage applied to electrode fingers 30a and 30b of inner stator electrode components 30 is passed via meander-shaped seesaw springs 53. In addition, the ground potential applied to electrode fingers 24a, 26a and 26b of actuator electrode components 24 and 26 is also passed via meander-shaped seesaw springs 53. The ground potential may be passed via a first meander-shaped seesaw spring 53 and the high-voltage signal is passed via a second meander-shaped seesaw spring 53. The lines for applying a high potential to electrode fingers 30a or 30b of inner stator electrode components 30 may also be routed via components 57 and 58.

Instead of using meander-shaped seesaw springs 53, it is also possible to use V-springs. The potentials may in that case be passed via the V-springs. It is possible for two lines to be routed via one V-spring. In total, therefore, 4 lines may be routed via two V-springs. This may be advantageous for actuation and reading-out of sensing elements.

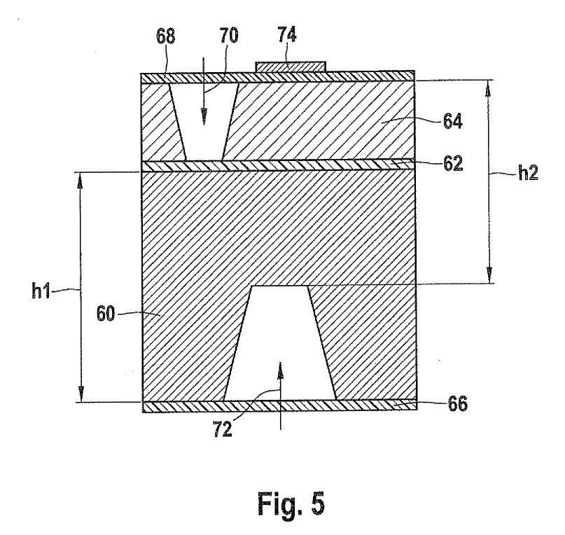

FIG. 5 shows a cross-section through a layer structure to illustrate an embodiment of the production method.

Using the production method, only part of which is described, it is possible to produce, for example, the micromechanical component illustrated in FIG. 4. The method steps performed in order to produce the micromechanical component of FIG. 4 will be apparent to one skilled in the art by reference to the layer structure described hereafter.

The layer structure includes a first semiconductor layer 60, an insulation layer 62 at least partially covering first semiconductor layer 60, and a second semiconductor layer 64 covering insulation layer 62. Openings which connect regions of semiconductor layers 60 and 64 to each other in one piece may be formed in insulation layer 62. First semiconductor layer 60 is, for example, a silicon substrate. Insulation layer 62, which may also be referred to as a buried oxide layer, may include an oxide and/or a different insulating material. Second semiconductor layer 64 may, in particular, be an SOI (silicon on insulator) layer.

A rear side of first semiconductor layer 60, oriented away from insulation layer 62, is covered at least partially by a rear-side layer 66, which may be made of an oxide. Correspondingly, an outer surface of second semiconductor layer 64 is covered at least partially by an upper-side layer 68 which may similarly contain an oxide.

Using processes known to the person skilled in the art, for example a lithographic process, continuous openings may be formed in layers 66 and 68. Thus, it is possible to etch first openings 70 in second semiconductor layer 64 via a front-side trench and second openings 72 in first semiconductor layer 60 via a rear-side trench. In that manner, components 10 through 30 and 50 through 58 of the micromechanical component of FIG. 4 may be patterned out of the layer structure illustrated. Suitable etching processes, such as, for example, KOH etching, will be apparent to the person skilled in the art by reference to FIG. 5.

The holder is shaped, for example, out of the material of the first semiconductor layer with a height h1 equal to the layer thickness of first semiconductor layer 60. Webs 50, 54 through 58 and mirror plate 10 may be formed by etching of openings 70 and 72 with a height h2 out of regions of semiconductor layers 60 and 64 and insulation layer 62. Springs 16, 52 and 53 may be patterned exclusively out of regions of second semiconductor layer 64, the layer thickness of which is smaller than the layer thickness of first semiconductor layer 60. This ensures advantageous values for the spring stiffness of springs 16, 52 and 53.

Since the patterning of actuator electrode fingers 24a, 26a and 26b in an out-of-plane position in relation to stator electrode fingers 28a, 30a and 30b will be apparent to the person skilled in the art by reference to FIGS. 4 and 5, this will not be discussed.

By forming at least one metal layer 74 on the upper-side layer 68, which may be on aluminum, lines for applying potentials to electrode fingers 24a, 26a, 26b, 28a, 30a and 30b may be produced in a simple manner and at little cost.

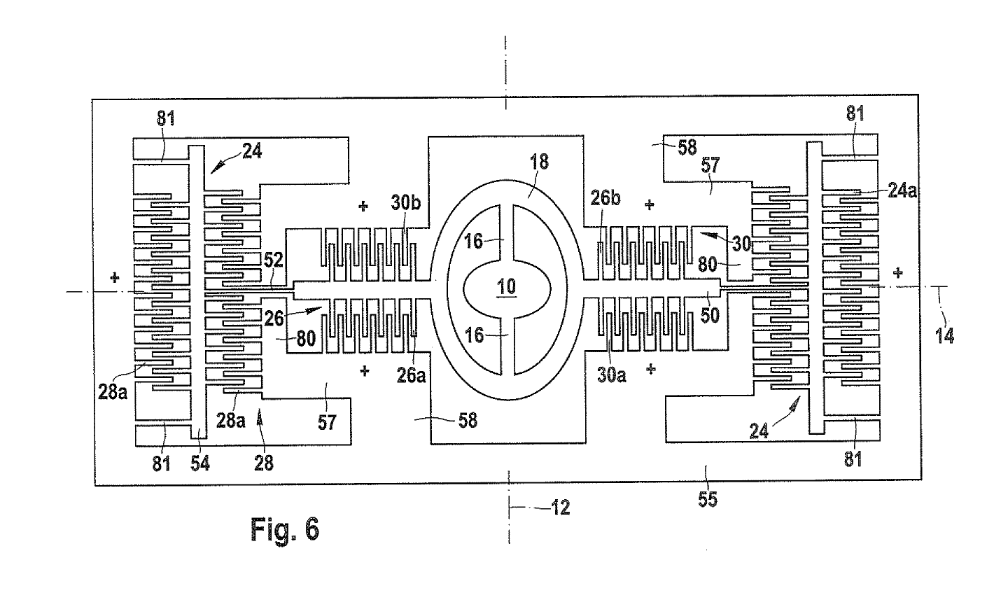

FIG. 6 shows a schematic illustration of a third embodiment of the micromechanical component.

In the case of the embodiment illustrated, electrode fingers 30a and 30b of the inner stator electrode components are fastened to the holder in the form of outer frame 55 via webs 57 and 58. This allows a more robust construction of webs 57 and 58 and makes it easier to provide lines connecting electrode fingers 30a and 30b of the inner stator electrode component to a voltage source.

The embodiment illustrated with the aid of FIG. 6 furthermore has the advantage that a comparatively small mass is adjusted by the torques caused by electrode components 24 through 30. Thus, comparatively small voltages at electrode components 24 through 30 will already bring about the desired displacement of mirror plate 10.

In addition, additional webs 80 may be fastened to webs 57 of the inner stator electrode component, which additional webs 80 are oriented parallel to second webs 54 of outer actuator electrode component 24. Further electrode fingers 28a of outer stator electrode component 28 may be formed on additional webs 80. In that case, electrode fingers 24a may be formed on both sides of second web 54 of outer actuator electrode component 24. In that manner it is possible to increase the number of electrode fingers 24a and 28a of outer electrode components 24 and 28 and obtain a greater torque for adjusting mirror plate 10 about first rotation axis 12. The compact configuration of webs 57 and 58 ensures a sufficient mounting area for lines for applying a potential to electrode fingers 28a that are formed on additional webs 80.

In contrast to the embodiment of FIG. 4 described in the foregoing, the outer springs are constructed as web-shaped flexible springs 81 oriented parallel to second rotation axis 14. Each flexible spring 81 connects one end of a second web 54 of outer actuator electrode components 24 to an adjacent inner surface of outer frame 55, which inner surface extends parallel to second web 54. The properties of such an outer spring will be discussed in more specific detail hereinafter. Instead of using at least one flexible spring 81, it is also possible to use at least one meander spring.

The extent of the micromechanical component along first rotation axis 12 is comparatively small, since an intermediate frame is not required and flexible springs 81 are not oriented along first rotation axis 12.

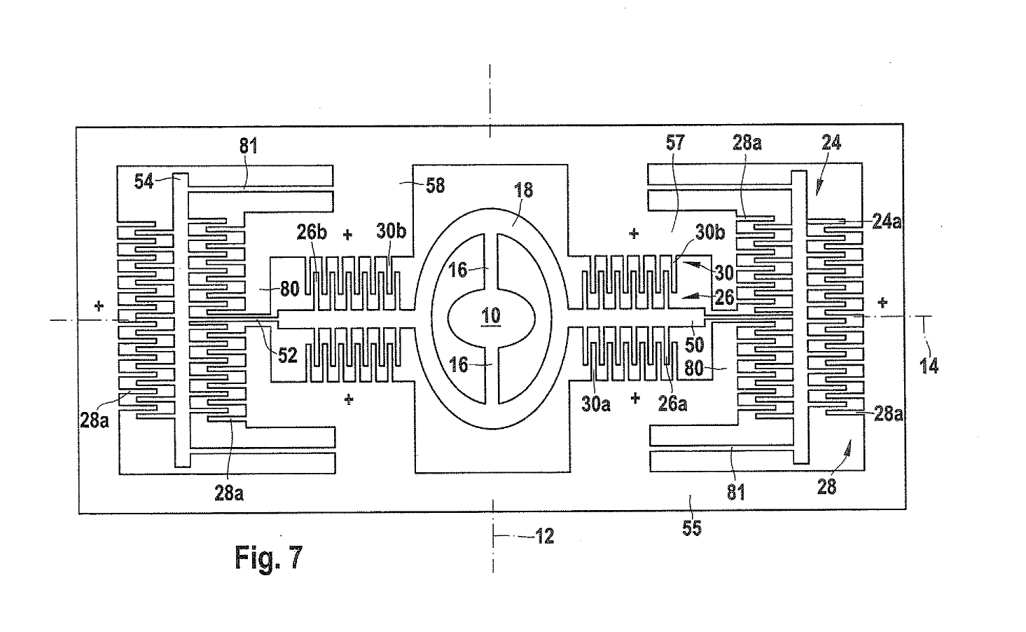

FIG. 7 shows a schematic illustration of a fourth embodiment of the micromechanical component.

Unlike the embodiment described in the foregoing, in the case of the micromechanical component illustrated in FIG. 7 the outer springs are constructed as web-shaped flexible springs 81 connecting one end of a second web 54 of an outer actuator electrode component 24 to a connecting web 58. This may also be described as an inward bracing of outer springs/flexible springs 81. With such an arrangement of flexible springs 81, it is possible to increase the lengths of the outer springs without lengthening an extent of the illustrated micromechanical component along second rotation axis 14. By virtue of the longer configuration of flexible springs 81 it is possible to reduce the spring stiffness of flexible springs 81 for the same width. That ensures better adjustability of Outer actuator electrode components 24 about first rotation axis 12.

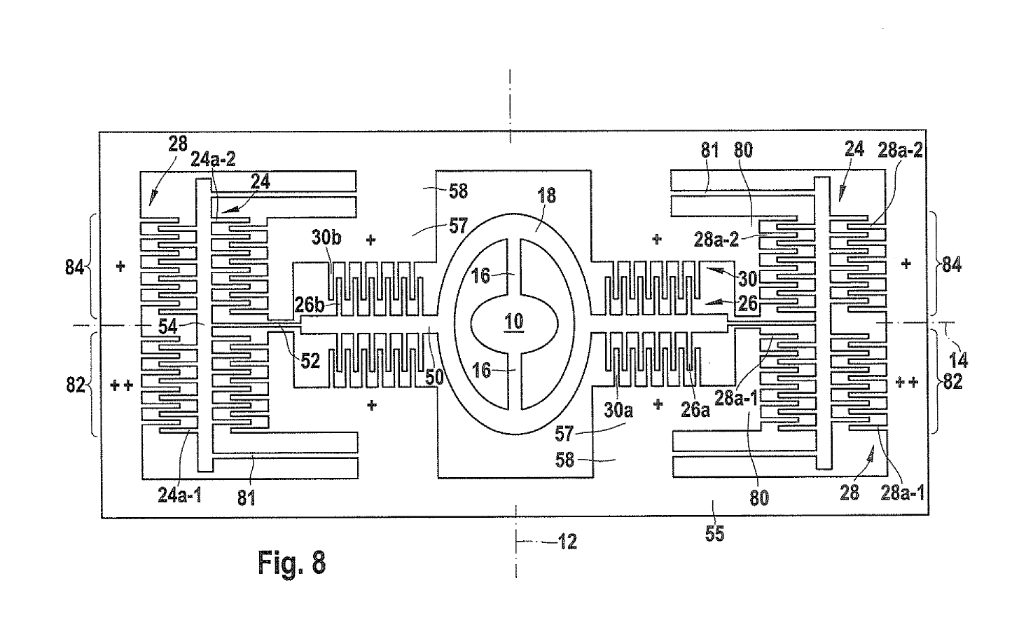

FIG. 8 shows a schematic illustration of a fifth embodiment of the micromechanical component.

In the case of the micromechanical component illustrated, outer electrode components 24 and 28 cooperating on one side of first rotation axis 12 are so constructed that a first voltage value may be applied as the first voltage between electrode fingers 24a-1 and 28a-1 belonging to cooperating outer electrode components 24 and 28 and disposed on the first side of second rotation axis 14, and a second voltage value, different from the first voltage value, may be applied as the first voltage between electrode fingers 24a-2 and 28a-2 belonging to cooperating outer electrode components 24 and 28 and disposed on the second side of second rotation axis 14.

This may also be described as subdivision of electrode fingers 24a and 28a, which belong to at least one of cooperating outer electrode components 24 and 28 and which act as electrode surfaces, by second rotation axis 14 into first electrode surfaces 24a-1 or 28a-1 disposed on a first side of second rotation axis 14 and into second electrode surfaces 24a-2 or 28a-2 disposed on a second side of the second rotation axis, first electrode surfaces 24a-1 or 28a-1 being coupled to at least one first line (not illustrated) in such a manner that a first potential may be applied to first electrode surfaces 24a-1 or 28a-1, and second electrode faces 24a-2 or 28a-2 being coupled to at least one second line (not shown) in such a manner that a second potential, different from the first potential, may be applied to second electrode surfaces 24a-2 or 28a-2. The micromechanical component may include a control device configured to apply the first potential to first electrode surfaces 24a-1 or 28a-1 and the second potential to second electrode surfaces 24a-2 or 28a-2.

A possible embodiment of such a micromechanical component is discussed in more specific detail below:

In the case of the embodiment illustrated, each outer stator electrode component 28 is subdivided into a first subcomponent 82 and a second subcomponent 84. First subcomponent 82 includes electrode fingers 28a-1 of associated outer stator electrode component 28 which are disposed on the first side of second rotation axis 14. Electrode fingers 28a-1 of first subcomponent 82 may be disposed on an inner surface of outer frame 55, which inner surface is oriented parallel to second web 54, and/or may be disposed on an outer surface of additional web 80. Correspondingly, electrode fingers 28a-2 belonging to outer stator electrode component 28 and disposed on the second side of second rotation axis 14 are assigned to second subcomponent 84. Electrode fingers 28a-2 of second subcomponent 84 may also be fastened to outer frame 55 and/or to additional web 80.

A first potential may be applied to electrode fingers 28a-1 of first subcomponent 82. At the same time, a second potential, which is different from the first potential, may be applied to electrode fingers 28a-2 of second subcomponent 84. The lines that belong to the two subcomponents 82 and 84 of outer stator electrode component 28 and that may be used for contacting electrode fingers 28a-1 and 28a-2 will be apparent to the person skilled in the art by reference to FIG. 8. This will not, therefore, be discussed in detail.

The subdivision of the at least one outer stator electrode component 28 into subcomponents 82 and 84 results in the advantage that sufficient mounting area is available on the holder, for example in the form of outer frame 55, for forming the lines of subcomponents 82 and 84. Furthermore, the formation of the lines of subcomponents 82 and 84 is made easier by the compact configuration of webs 57 and 58.

It is pointed out, however, that the micromechanical component is not limited to a subdivision of at least one outer stator electrode component 28 into subcomponents 82 and 84 with respect to second rotation axis 14. Instead of or in addition to the at least one subdivided outer stator electrode component 28, at least one outer actuator electrode component 24 may also be subdivided in such a manner that different potentials may be applied to electrode fingers 24a-1 and 24a-2 disposed on the two sides of second rotation axis 14. Since such a configuration of the micromechanical component will be apparent to the person skilled in the art by reference to FIG. 8, this will not be discussed further.

By applying a first voltage value between electrode fingers 24a-1 and 28a-1 belonging to cooperating outer electrode components 24 and 28 and disposed on the first side of second rotation axis 14 and by applying the second voltage value, which is different from the first voltage value, between electrode fingers 24a-2 and 28a-2 belonging to the same outer electrode components 24 and 28 and disposed on the second side of second rotation axis 14, it is possible for an additional torque to be exerted about second rotation axis 14 on outer actuator electrode component 24. In an exemplary embodiment, the first voltage value and the second voltage value are provided by the control device in such a manner that the additional torque on outer actuator electrode component 24 about second rotation axis 14 compensates for an additional torque caused by adjacent inner actuator electrode component 26 upon adjustment of inner actuator electrode component 26 about second rotation axis 14. This may be accomplished by the control device being additionally configured to determine a difference between the applied first potential/the first voltage value and the second potential/the second voltage value, taking into consideration information relating to the second voltage present between the at least one electrode finger 26a or 26b of inner actuator electrode component 26 and inner stator electrode component 30 and/or relating to a current position of the at least one electrode finger 26a or 26b of inner actuator electrode component 26 in relation to inner stator electrode component 30.

In that manner it is possible to prevent the crosstalk which occurs in the case of a conventional micromechanical component as a result of concomitant movement of outer actuator electrode component 24 upon adjustment of adjacent inner actuator electrode component 26 about second rotation axis 14. The undesirable coupling which occurs between the two adjustment movements of mirror plate 10 in the related art may thus be suppressed in such a manner that it does not impair or hardly impairs a desired adjustment of mirror plate 10.

The subdivision of at least one outer electrode component 24 or 28 into the two subcomponents 82 and 84 and the application of differing voltage values between electrode surfaces 24a-1, 24a-2, 28a-1 and 28a-2 of cooperating outer electrode components 24 and 28 on the two sides of second rotation axis 14 may also be described as operation of the micromechanical component in closed-loop operation. It is pointed out once again that, in the case of such closed-loop operation, two cooperating outer electrode components 24 and 28 which are so constructed that, by application of the first voltage to electrode fingers 24a-1, 24a-2, 28a-1 and 28a-2, the mirror plate is adjustable about first rotation axis 12, electrode fingers 24a-1, 24a-2, 28a-1 and 28a-2 are subdivided in such a manner that the first voltage value may be applied between electrode fingers 24a-1 and 28a-1 disposed on the first side of second rotation axis 14 and the second voltage value, which is different from the first voltage value, may be applied between electrode fingers 24a-2 and 28a-2 disposed on the second side of second rotation axis 14.

The embodiments of the micromechanical component that are illustrated in FIGS. 4 and 6 may, in a development, also be operated in closed-loop operation. Since developments suitable for closed-loop operation will be apparent to the person skilled in the art from the foregoing paragraphs, this will not be discussed in greater detail.

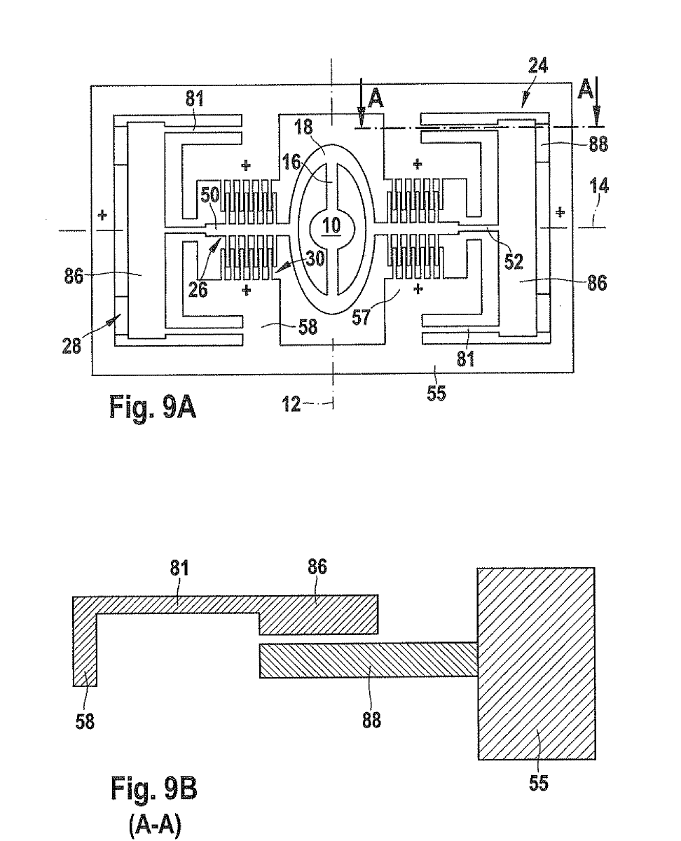

FIGS. 9A and 9B show schematic illustrations of a sixth embodiment of the micromechanical component.

The embodiment shown in plan view in FIG. 9A has an outer electrical plate drive instead of an outer electrical comb drive. Outer actuator electrode component 24 is in this case constructed as an actuator plate electrode 86 which is connected to first web 50 of adjacent inner actuator electrode component 26 by intermediate spring 52 extending along second rotation axis 14. In its starting position (in no-voltage operation), actuator plate electrode 86 may be oriented parallel to a plane defined by the two rotation axes 12 and 14. Actuator plate electrode 86 is connected to the holder directly or indirectly via at least one outer spring. The at least one outer spring may, for example, include a flexible spring 81. In the case of the embodiment illustrated, two flexible springs 81 extend between actuator plate electrode 86 and an adjacent connecting web 58 and parallel to second rotation axis 14. Further possible embodiment examples for the at least one outer spring that connects actuator plate electrode 86 directly or indirectly to the holder will also be apparent to the person skilled in the art by reference to the Figures shown herein.

Outer stator electrode component 28 also may be constructed as at least one stator plate electrode 88. As will be seen by reference to the cross-section shown in FIG. 9B through FIG. 9A along line A-A, the at least one stator plate electrode 28 may be oriented at a minimal distance from and parallel to the starting position of actuator plate electrode 86. Advantageously, plate electrodes 86 and 88 may have overlapping surfaces. The distance between the overlapping surfaces may be only a few micrometers. That ensures a relatively great torque for adjusting mirror plate 10 about first rotation axis 12 by using plate electrodes 86 and 88.

In a development of the embodiment illustrated, at least one of cooperating outer electrode components 24 and 28 may be subdivided into subcomponents. In that case, at least one of outer electrode components 24 and 28 has a first partial plate electrode on the first side of second rotation axis 14 and a second partial plate electrode on the second side of second rotation axis 14. Accordingly, a first voltage value may be applied between first electrode surfaces belonging to cooperating outer electrode components 24 and 28 and disposed on the first side of second rotation axis 14 and a second voltage value, different from the first voltage value, may be applied between second electrode surfaces belonging to cooperating outer electrode components 24 and 28 and disposed on the second side of second rotation axis 14.

In that manner it is also possible for an additional torque to be applied to outer actuator electrode component 24 by cooperating outer electrode components 24 and 28 of electrical plate drive, which additional torque opposes concomitant movement of outer actuator electrode component 24 upon adjustment of adjacent inner actuator electrode component 26 about second rotation axis 14. Such a development of the electrical plate drive and the lines that are required for contacting the plate drive will be apparent to the person skilled in the art by reference to the description given herein. Such a development will not, therefore, be discussed in greater detail.

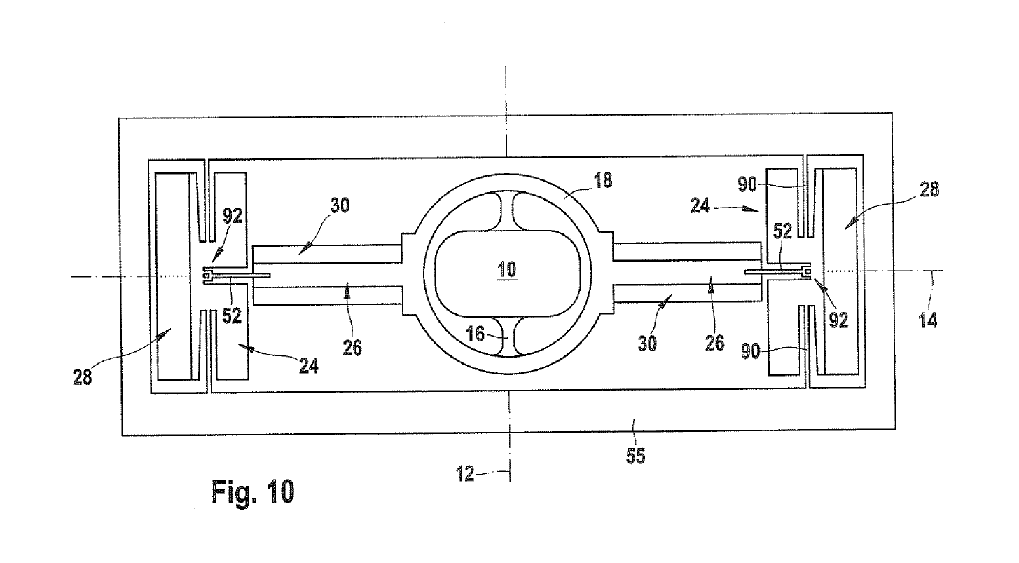

FIG. 10 shows a schematic illustration of a seventh embodiment of the micromechanical component.

One possibility for suppressing crosstalk, that is, concomitant movement of outer actuator electrode component 24 upon adjustment of adjacent inner actuator electrode component 26 about the second rotation axis, consists in a suitable configuration and positioning of the at least one outer spring via which outer actuator electrode component 24 is connected to the holder.

A first spring stiffness of intermediate spring 52 in respect of torsion of intermediate spring 52 about second rotation axis 14 may be smaller than a second spring stiffness of the at least one outer spring which opposes rotational motion of outer actuator electrode component 24 about second rotation axis 14. This may be accomplished in a simple manner by so configuring and arranging the outer spring or a spring suspension formed from a plurality of outer springs that a first flexural rigidity of the at least one outer spring in respect of a first adjustment movement of outer actuator electrode component 24 along a first movement direction perpendicular to the two rotation axes 12 and 14 is relatively low. In addition, it is advantageous if a second flexural rigidity of the outer spring or the spring suspension in respect of a second adjustment movement of outer actuator electrode component 24 along a second movement direction, which is oriented non-parallel to the first movement direction, is comparatively great. Suitable advantageous embodiment examples of the at least one outer spring for ensuring an advantageous first flexural rigidity and second flexural rigidity have already been illustrated in the preceding Figures.

In the case of the micromechanical component illustrated in FIG. 10, each outer actuator electrode component 24 is connected to the holder in the form of outer frame 55 via two torsion springs 90 oriented parallel to first rotation axis 12. Torsion springs 90 may be of a web-shaped configuration.

By arranging outer actuator electrode component 24 on outer frame 55 via the two torsion springs 90 it is ensured that outer actuator electrode component 24 is capable of being adjusted in the desired first adjustment direction perpendicular to the two rotation axes 12 and 14 by a comparatively small force. By contrast, a comparatively great force is needed to move outer actuator electrode component 24 in the second adjustment direction which is non-parallel to the first adjustment direction. This may also be described as the two torsion springs 90 being configured for what may be preferential translational motion (perpendicular to the two rotation axes 12 and 14) of outer actuator electrode component 24. The two torsion springs 90 cooperate in this case as a bilaterally fixed flexible spring.

In addition, an intermediate spring 52 may have a continuous opening at an end portion adjacent to the outer actuator electrode component, which opening subdivides the end portion into a first arm and a second arm. The end portion may be subdivided in such a manner that the two arms and a connecting web extending between the two arms form a U-shaped spring link 92.

As the person skilled in the art will appreciate, outer electrode components 24 and 28 of the embodiment illustrated and of the embodiments described hereafter may be constructed as a comb drive and/or as a plate drive. The electrode surfaces for applying a potential of at least one outer electrode component 24 and 28 may, in addition, be subdivided with respect to second rotation axis 14. Such a development of the embodiments will be apparent from the foregoing paragraphs.

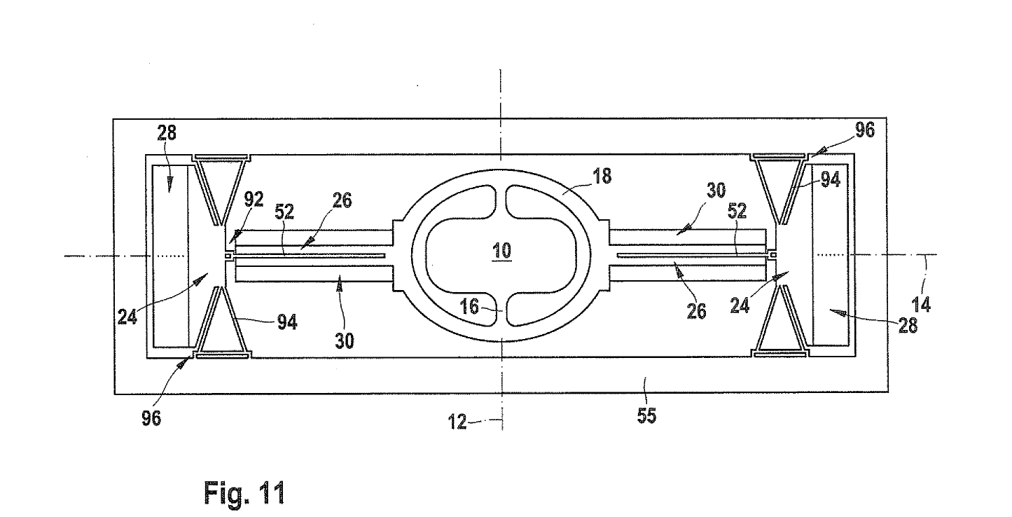

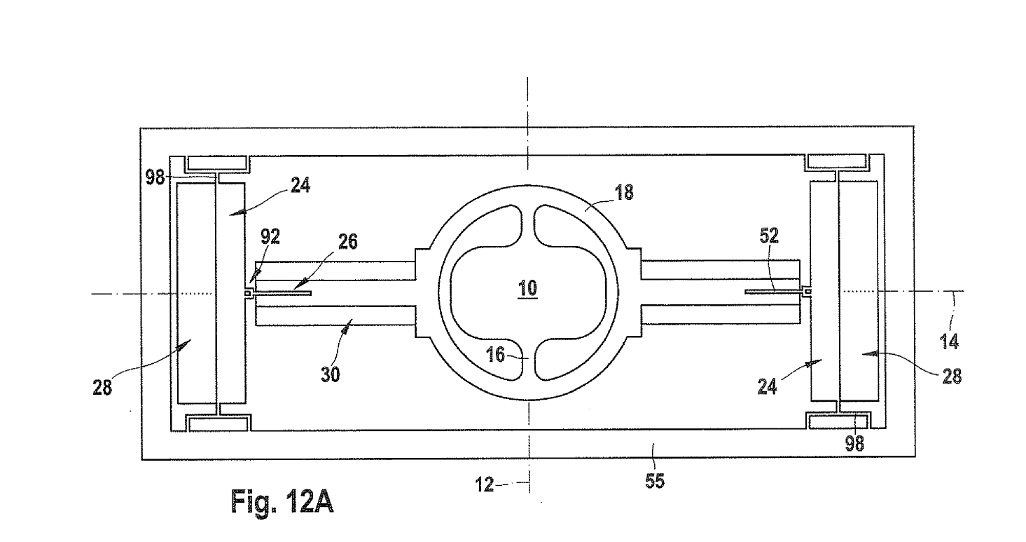

FIG. 11 shows a schematic illustration of an eighth embodiment of the micromechanical component.

Each outer actuator electrode component 24 of the illustrated micromechanical component is connected to the holder in the form of outer frame 55 via two V-springs 94. The V-springs 94 may be so constructed that their axes of symmetry extend parallel to first rotation axis 12. In that manner it is ensured that the assembly of the two V-springs 94 of an outer actuator electrode component 24, which may also be described as an X-shaped spring assembly, has a relatively small first flexural rigidity in respect of the first adjustment movement of outer actuator electrode component 24 along the first adjustment direction perpendicular to the two rotation axes 12 and 14. By contrast, the second flexural rigidity of the X-shaped spring assembly for a second adjustment direction which is oriented non-parallel to the first adjustment direction is comparatively great. Accordingly, it is also possible for crosstalk, that is, undesirable coupling between the two adjustment movements of mirror plate 10, to be suppressed using the X-shaped spring assembly formed by the two V-springs 94. Furthermore, V-springs 94 may be connected to outer frame 55 via a U-shaped spring link 96.

Inner actuator electrode components 26 that are reproduced merely schematically in FIG. 11 have a recess at the side thereof facing toward adjacent intermediate spring 52, which recess at least partially encompasses intermediate spring 52. Accordingly, at least a portion of intermediate spring 52 extends inside the recess. In that manner it is possible for intermediate springs 52 to have an advantageously great length and hence a low first spring stiffness and good flexibility about second rotation axis 14 although the micromechanical component has a comparatively small extent along second rotation axis 14. In addition, intermediate springs 52 may be connected to adjacent outer actuator electrode component 24 via U-shaped spring link 92.

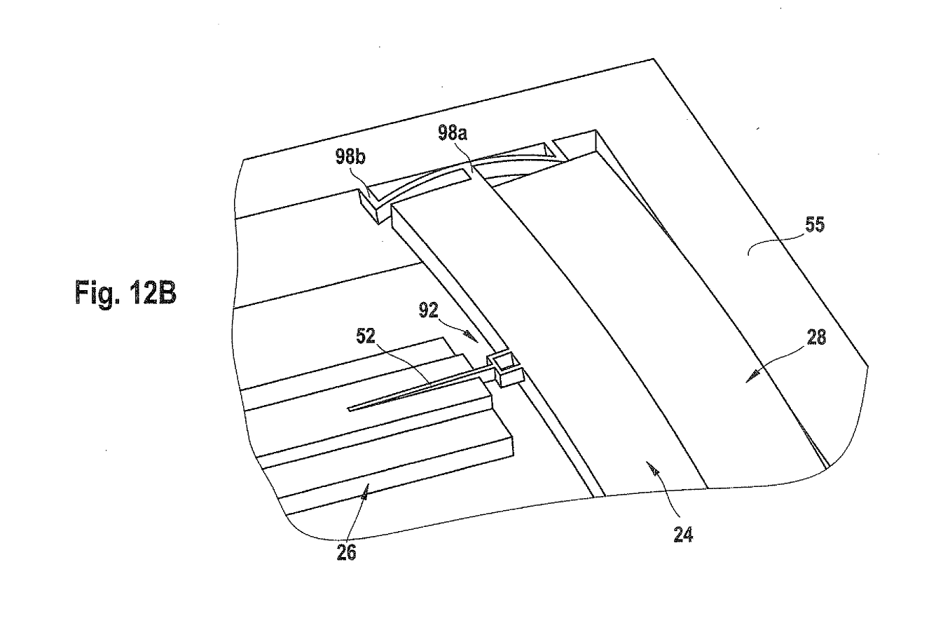

FIGS. 12A and 12B show schematic illustrations of a ninth embodiment of the micromechanical component.

The micromechanical component shown in plan view in FIG. 12A has two outer actuator electrode components 24 each connected to outer frame 55 via two bilaterally fixed flexible springs 98. As will be seen by reference to the enlarged view in FIG. 12B, each bilaterally fixed flexible spring 98 includes a web-shaped inner portion 98a and an outer portion 98b which is constructed as a U-shaped spring link. Inner portion 98a contacts adjacent outer actuator electrode component 24. Outer portion 98b contacting outer frame 55 is so constructed that a central spacing between the two outer surfaces of the two arms of outer portion 98b is distinctly larger than a central width of inner portion 98a. The two bilaterally fixed flexible springs 98 may be positioned on outer actuator electrode component 24 in such a manner that their axes of symmetry are oriented parallel to first rotation axis 12.

By virtue of bilaterally fixed flexible springs 98, it is possible for the desired translational motion of outer actuator electrode component 24 perpendicular to the two rotation axes 12 and 14 to be reliably obtained.

In the case of the embodiment of FIGS. 12A and 12B also, intermediate spring 52 is connected to adjacent outer actuator electrode component 24 via U-shaped spring link 92 and extends at least partially through a recess formed in associated inner actuator electrode component 26.

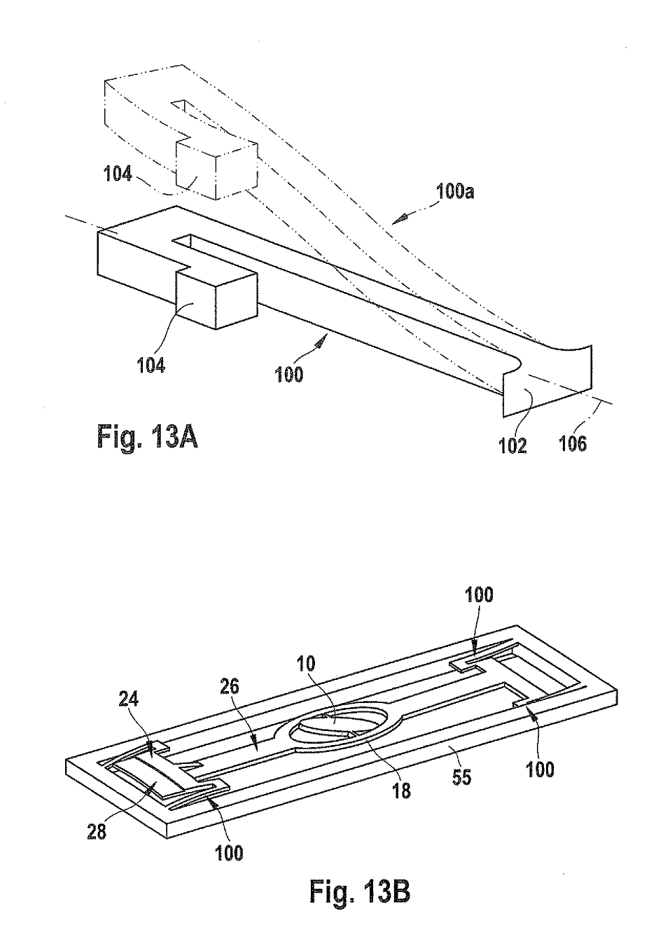

FIGS. 13A and 13B shows a tenth embodiment of the micromechanical component.

In FIG. 13A, a meander-shaped spring 100 is shown on a larger scale. Meander-shaped spring 100 has at least one meander. A construction involving a plurality of turns/meanders of meander-shaped spring 100 will be apparent to the person skilled in the art by reference to FIG. 13A.

Meander-shaped spring 100 may be fastened at a first end portion 102 to a holder in the form of, for example, outer frame 55. Meander-shaped spring 100 may also contact, at a second end portion 104, an outer actuator electrode component 24. Meander-shaped spring 100 may be patterned together with at least one subunit of the holder and/or of outer actuator electrode component 24 out of a semiconductor material, such as, for example, silicon. Since the production method for meander-shaped spring 100 will be apparent to the person skilled in the art by reference to FIGS. 13A and 13B, this will not be discussed in detail.

The application of a voltage between outer electrode components 24 and 28 causes meander-shaped spring 100 to bend out of a starting position into a bent position 100a.

As will be seen from the micromechanical component of FIG. 13B shown in side view, two meander-shaped springs 100 in each case are able to connect an outer actuator electrode component 24 to outer frame 55. First end portion 102 of meander-shaped spring 100 contacts an inner surface of outer frame 55, which inner surface may be oriented parallel to first rotation axis 12. Second end portion 104 is able to contact an outer surface of associated outer actuator electrode component 24, which outer surface is oriented parallel to second rotation axis 14.

Each of the two meander-shaped springs 100 of an outer actuator electrode component 24 contacts associated outer actuator electrode component 24 on a different side of second rotation axis 14. The longitudinal directions 106 of meander-shaped springs 100 are oriented parallel to second rotation axis 14.

Owing to the cooperation of the two meander-shaped springs 100 of the same outer actuator electrode component 24, a spring suspension is obtained, having an advantageous low first flexural rigidity in respect of the first adjustment movement of outer actuator electrode component 24 perpendicular to the two rotation axes 12 and 14. The second flexural rigidity of the spring suspension in respect of a second adjustment movement of outer actuator electrode component 24, which is non-parallel to the first adjustment movement, is significantly greater.

Altogether, therefore, the bending lines of the two meander-shaped springs 100 provide an overall spring relationship that favors a translational motion of outer actuator electrode component 24 perpendicular to the two rotation axes 12 and 14 and prevents crosstalk.

In the case of a purely translational motion of outer actuator electrode components 24, no lateral movements of outer actuator electrode components 24, which interfere with the desired movements of mirror plate 10, are produced. As a result, an additional energy input, which occurs in the case of the related art and which is invested in the undesired lateral movement, does not occur. Accordingly, an optimum energy input is obtained in the case of the embodiments described herein.

In addition, the electrostatic force produced is proportional to the change in surface area of electrode components 24 through 30. In the case of a purely translational motion of outer actuator electrode components 24, a change in surface area between outer electrode components 24 and 28 that is proportional to the length of electrode fingers 24a and 28a is obtained. In the case of the unwanted rotational motion of outer actuator electrode components 24, the change in surface area is half as great.

An additional lateral movement component also reduces the useful component of the excitation movement. Moreover, an additional lateral movement component causes a shift in the middle point of mirror plate 10, which makes it necessary to enlarge mirror plate 10 in order to ensure that a light beam impinges on the surface of mirror plate 10 during the adjustment movement of the mirror plate. Using the forms of construction and developments described herein, it is possible to avoid that disadvantage of the related art.

In addition to the shape of the outer springs, the suspension points of the outer springs may also be varied in order to obtain a purely translational motion of outer electrode components 24, that is, a motion perpendicular to the two rotation axes 12 and 14. Since such modifications of the embodiments shown herein will be apparent to the person skilled in the art from the Figures, this will not be discussed further.

1-11. (canceled)

12. A micromechanical component, comprising:
a holder;
an adjustable element;
an outer stator electrode component and an outer actuator electrode component, the outer actuator electrode component being connected to the holder via at least one outer spring and the adjustable element being coupled to the outer actuator electrode component so that the adjustable element is adjustable in relation to the holder about a first rotation axis by application of a first voltage between the outer actuator electrode component and the outer stator electrode component; and
an inner stator electrode component and an inner actuator electrode component, the inner actuator electrode component including a first web with at least one electrode finger disposed thereon and the first web being oriented along a second rotation axis which is non-parallel to the first rotation axis, and the adjustable element being coupled to the inner actuator electrode component so that the adjustable element is adjustable in relation to the holder about the second rotation axis by application of a second voltage between the at least one electrode finger of the inner actuator electrode component and the inner stator electrode component;
wherein an intermediate spring is oriented along the second rotation axis and via which the inner actuator electrode component is connected to the outer actuator electrode component.

13. The micromechanical component of claim 12, wherein a first spring stiffness of the intermediate spring in respect of torsion of the intermediate spring about the second rotation axis is smaller than a second spring stiffness of the at least one outer spring which opposes rotational motion of the outer actuator electrode component about the second rotation axis.

14. The micromechanical component of claim 12, wherein the outer actuator electrode component includes a second web oriented non-parallel to the first web and having at least one electrode finger disposed thereon.

15. The micromechanical component of claim 12, wherein the outer actuator electrode component includes a plate electrode.

16. The micromechanical component of claim 12, wherein a side of the inner actuator electrode component facing toward the adjacent outer actuator electrode component has a recess, and wherein the intermediate spring extends at least partially through the recess.

17. The micromechanical component of claim 12, wherein electrode surfaces of at least one of (i) the outer actuator electrode component, and (ii) the outer stator electrode component are subdivided by the second rotation axis into first electrode surfaces disposed on a first side of the second rotation axis and into second electrode surfaces disposed on a second side of the second rotation axis, and wherein the first electrode surfaces are coupled to at least one first line so that a first potential may be applied to the first electrode surfaces, and the second electrode surfaces are coupled to at least one second line so that a second potential, different from the first potential, may be applied to the second electrode surfaces.

18. The micromechanical component of claim 17, wherein the micromechanical component includes a control device configured to apply the first potential to the first electrode surfaces and the second potential to the second electrode surfaces, and wherein the control device is additionally configured to determine a difference between the first potential and the second potential taking into consideration information relating to at least one of (i) the second voltage present between the at least one electrode finger of the inner actuator electrode component and the inner stator electrode component, and (ii) a current position of the at least one electrode finger of the inner actuator electrode component in relation to the inner stator electrode component.

19. The micromechanical component of claim 12, wherein the at least one outer spring includes a spring which is oriented parallel to the first rotation axis and which is constructed as at least one of a meander-shaped seesaw spring, a torsion spring, a V-spring, and a bilaterally fixed flexible spring.

20. The micromechanical component of claim 12, wherein the at least one outer spring includes a spring which is oriented parallel to the second rotation and which is constructed as at least one of a flexible spring and a meander-shaped spring.

21. The micromechanical component of claim 12, wherein owing to at least one of (i) a shape of the at least one outer spring, and (ii) the suspension points of the at least one outer spring, the outer actuator electrode component is capable of being set into motion oriented perpendicularly to the first rotation axis and the second rotation axis.

22. A production method for a micromechanical component, the method comprising:
forming an outer stator electrode component and an outer actuator electrode component, the outer actuator electrode component being connected to the holder of the micromechanical component via at least one outer spring;
coupling an adjustable element to the actuator electrode component so that the adjustable element is adjusted in relation to the holder about a first rotation axis upon application of a first voltage between the outer actuator electrode component and the outer stator electrode component;
forming an inner stator electrode component and an inner actuator electrode component having a first web and at least one electrode finger disposed on the first web, the first web being oriented along a second rotation axis which is non-parallel to the first rotation axis;
coupling the adjustable element to the inner actuator electrode component so that the adjustable element is adjusted in relation to the holder about the second rotation axis upon application of a second voltage between the at least one electrode finger of the inner actuator electrode component and the inner stator electrode component; and
connecting the inner actuator electrode component to the outer actuator electrode component via an intermediate spring which is oriented along the second rotation axis.
